(19) United States
(12) Patent Application Publication
(10) Pub. No.: US 2025/0374582 A1
(43) Pub. Date: Dec. 4, 2025

(54) SEMICONDUCTOR DEVICE AND METHOD OF MANUFACTURING THE SAME

(71) Applicant: Renesas Electronics Corporation, Tokyo (JP)

(72) Inventor: Yotaro GOTO, Tokyo (JP)

(21) Appl. No.: 19/175,037

(22) Filed: Apr. 10, 2025

(30) Foreign Application Priority Data
Jun. 3, 2024 (JP) 2024-089917

(51) Int. Cl. H10D 30/01; H10D 30/65; H10D 62/10; H10D 64/00; H10D 64/01; H10D 64/66

(52) U.S. Cl. CPC H10D 30/0285; H10D 30/65; H10D 62/107; H10D 64/021; H10D 64/111; H10D 64/663

(57) ABSTRACT

A position of an upper surface of a lead-out portion of a gate electrode is higher than an upper surface of an active portion of the gate electrode. An insulating film has a first raised portion positioned on a side surface of the active portion of the gate electrode via a sidewall spacer and a second raised portion positioned on a side surface of the lead-out portion of the gate electrode via the sidewall spacer. An active portion of a field plate electrode is in contact with the first raised portion, and a position of an uppermost portion of the lead-out portion of the field plate electrode is lower than a position of an uppermost portion of the insulating film positioned over the upper surface of the lead-out portion of the gate electrode.

### CROSS-REFERENCE TO RELATED APPLICATIONS

The disclosure of Japanese Patent Application No. 2024-089917 filed on Jun. 3, 2024 including the specification, drawings and abstract is incorporated herein by reference in its entirety.

### BACKGROUND

The present invention relates to a semiconductor device and a method of manufacturing the same.

There are disclosed techniques listed below.
[Patent Document 1] Japanese Unexamined Patent Application Publication No. 2018-50048

Patent Document 1 discloses a Laterally Diffused Metal Oxide Semiconductor (LDMOS) as a type of Metal Insulator Semiconductor Field Effect Transistor (MISFET). The LDMOS has a low-concentration drift region disposed between a drain region and a gate electrode with high concentrations.

In a semiconductor device including a plurality of LDMOSs, the LDMOSs are disposed in line symmetry with a drain region or a source region as axes, and the LDMOSs adjacent to each other share the drain region or the source region. A drift region having an concentration lower than the impurity concentration of the drain region is formed between a semiconductor substrate positioned under the end of the gate electrode and the drain region.

In addition, a field plate electrode is formed on a portion from the drift region to an upper surface of the gate electrode. Since the electric field tends to concentrate in the vicinity of the end of the gate electrode, applying the field plate electrode can relax the electric field in the vicinity of the end of the gate electrode, thus improving the withstand voltage of the LDMOS.

When the field plate electrode is applied, the field plate electrode is formed on the semiconductor substrate so as to cover the upper surface of the gate electrode. Since a semiconductor device includes other MISFETs in addition to the LDMOS, the height of the LDMOS tends to be larger than the height of the other MISFETs due to the thickness of the field plate electrode. As a result, the thickness of an interlayer insulating film formed on the LDMOS tends to be smaller than the thickness of an interlayer insulating film formed on another MISFET.

Thus, if there is a peculiar portion where the thickness of the interlayer insulating film is partially small, an unexpected defect may occur in the subsequent manufacturing process. For example, when the interlayer insulating film includes a lower layer film and an upper layer film made of a material different from that of the lower layer film, the lower layer film may not be covered with the upper layer film and may be exposed at the peculiar portion. Then, since the material of the interlayer insulating film at the peculiar portion is different from the material of the interlayer insulating film at other portions, even if the same manufacturing process is performed thereafter, the unexpected defect is likely to occur at the peculiar portion, which may lower the reliability of the semiconductor device.

Other problems and novel features will become apparent from the description of the present specification and the accompanying drawings.

### SUMMARY

In one embodiment, a semiconductor device includes: a semiconductor substrate having an upper surface and a lower surface; an element isolation portion formed in the semiconductor substrate; a gate insulating film formed on the upper surface of the semiconductor substrate; a gate electrode formed on the gate insulating film and on an upper surface of the element isolation portion; a sidewall spacer formed on a side surface of the gate electrode; a first insulating film formed over the upper surface of the semiconductor substrate and over the upper surface of the element isolation portion so as to cover an upper surface of the gate electrode and the sidewall spacer; and a field plate electrode formed on the first insulating film. The gate electrode has a first portion positioned over the upper surface of the semiconductor substrate and a second portion positioned over the upper surface of the element isolation portion. The first insulating film includes a third portion positioned over the upper surface of the semiconductor substrate, a fourth portion positioned above the third portion and positioned on the side surface of the first portion of the gate electrode via the sidewall spacer, a fifth portion positioned over the upper surface of the element isolation portion, and a sixth portion positioned above the fifth portion and positioned on the side surface of the second portion of the gate electrode via the sidewall spacer. The field plate electrode has a seventh portion positioned over the upper surface of the semiconductor substrate and an eighth portion positioned over the upper surface of the element isolation portion. A position of the upper surface of the second portion of the gate electrode is higher than a position of the upper surface of the first portion of the gate electrode. The seventh portion of the field plate electrode is in contact with the fourth portion of the first insulating film, and a position of the uppermost portion of the eighth portion of the field plate electrode is lower than a position of the uppermost portion of the first insulating film positioned over the upper surface of the second portion of the gate electrode.

In one embodiment, a method of manufacturing a semiconductor device includes: (a) preparing a semiconductor substrate having an upper surface and a lower surface; (b) forming an element isolation portion in the semiconductor substrate so as to reach a predetermined depth from the upper surface of the semiconductor substrate; (c) forming a gate insulating film on the upper surface of the semiconductor substrate; (d) forming a gate electrode on the gate insulating film and on an upper surface of the element isolation portion; (e) forming a sidewall spacer on a side surface of the gate electrode; (f) forming a first insulating film over the upper surface of the semiconductor substrate and the upper surface of the element isolation portion so as to cover an upper surface of the gate electrode and the sidewall spacer; and (g) forming a field plate electrode on the first insulating film. The gate electrode has a first portion positioned over the upper surface of the semiconductor substrate and a second portion positioned over the upper surface of the element isolation portion. The first insulating film includes a third portion positioned over the upper surface of the semiconductor substrate, a fourth portion positioned above the third portion and positioned on the side surface of the first portion of the gate electrode via the sidewall spacer, a fifth portion positioned over the upper surface of the element isolation portion, and a sixth portion positioned above the fifth portion and positioned on the side surface of the second portion of the gate electrode via the sidewall spacer. The field plate electrode has a seventh portion positioned over the upper surface of the semiconductor substrate and an eighth portion positioned over the upper surface of the element isolation portion. A position of the upper surface of the second portion of the gate electrode is higher than a position of the upper surface of the first portion of the gate electrode. The seventh portion of the field plate electrode is in contact with the fourth portion of the first insulating film, and a position of the uppermost portion of the eighth portion of the field plate electrode is lower than a position of the uppermost portion of the first insulating film positioned over the upper surface of the second portion of the gate electrode.

According to one embodiment, the reliability of the semiconductor device can be improved.

### BRIEF DESCRIPTION OF THE DRAWINGS

FIG. 1 is a plan view illustrating a semiconductor device according to a first embodiment.

FIG. 2 is a cross-sectional view illustrating the semiconductor device according to the first embodiment.

FIG. 3 is an enlarged cross-sectional view of a main part of FIG. 2.

FIG. 4 is a cross-sectional view illustrating the semiconductor device according to the first embodiment.

FIG. 5 is a cross-sectional view illustrating a manufacturing process of the semiconductor device according to the first embodiment.

FIG. 6 is a cross-sectional view illustrating a manufacturing process of the semiconductor device, which is a subsequent step to FIG. 5.

FIG. 7 is a cross-sectional view illustrating a manufacturing process of the semiconductor device, which is a subsequent step to FIG. 6.

FIG. is a cross-sectional view illustrating a manufacturing process of the semiconductor device according, which is a subsequent step to FIG. 7.

FIG. 9 is a cross-sectional view illustrating a manufacturing process of the semiconductor device according to the first embodiment, which is a subsequent step to FIG. 8.

FIG. 10 is a cross-sectional FIG. view illustrating a manufacturing process of the semiconductor device, which is a subsequent step to FIG. 9.

FIG. 11 is a cross-sectional view illustrating a manufacturing process of the semiconductor device, which is a subsequent step to FIG. 10.

FIG. 12 is a cross-sectional view illustrating a manufacturing process of the semiconductor device, which is a subsequent step to FIG. 11.

FIG. 13 is a cross-sectional view illustrating a manufacturing process of the semiconductor device, which is a subsequent step to FIG. 12.

FIG. 14 is a cross-sectional view illustrating a manufacturing process of the semiconductor device, which is a subsequent step to FIG. 13.

FIG. 15 is a cross-sectional view illustrating a manufacturing process of the semiconductor device, which is a subsequent step to FIG. 14.

FIG. 16 is a cross-sectional view illustrating a manufacturing process of the semiconductor device, which is a subsequent step to FIG. 15.

FIG. 17 is a cross-sectional view illustrating a manufacturing process of the semiconductor device, which is a subsequent step to FIG. 16.

FIG. 18 is a cross-sectional view illustrating a semiconductor device according to a second embodiment.

FIG. 19 is a plan view illustrating a semiconductor device according to a third embodiment.

FIG. 20 is a cross-sectional view illustrating the semiconductor device according to the third embodiment.

FIG. 21 is a cross-sectional view illustrating a manufacturing process of the semiconductor device according to the third embodiment.

FIG. 22 is a plan view illustrating a semiconductor device according to a fourth embodiment.

FIG. 23 is a cross-sectional view illustrating the semiconductor device according to the fourth embodiment.

FIG. 24 is a cross-sectional view illustrating a manufacturing process of the semiconductor device according to the fourth embodiment.

FIG. 25 is a plan view illustrating a semiconductor device according to an examination example.

FIG. 26 is a cross-sectional view illustrating the semiconductor device according to the examination example.

FIG. 27 is a cross-sectional view for explaining a problem in the examination example.

### DETAILED DESCRIPTION

Hereinafter, embodiments will be described in detail with reference to the drawings. In all the drawings for describing the embodiments, members having the same function are denoted by the same reference numerals, and repeated description thereof will be omitted. In addition, in the following embodiments, descriptions of the same or similar parts will not be repeated in principle unless particularly necessary.

An X direction, Y direction, and Z direction described in the present application intersect each other and are orthogonal to each other. In the present application, the Z direction will be described as a vertical direction, a depth direction, or a thickness direction of a certain structure. In addition, the expression such as “plan view” used in the present application means that a surface constituted by the X direction and the Y direction is a “plane” and this “plane” is viewed from the Z direction.

### First Embodiment

### <Structure of Semiconductor Device>

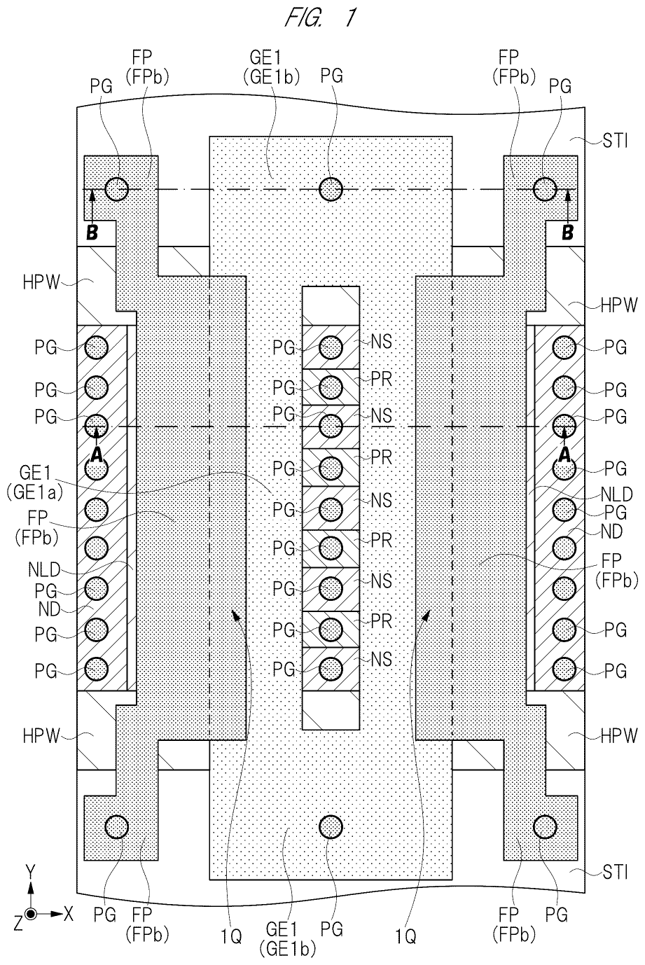

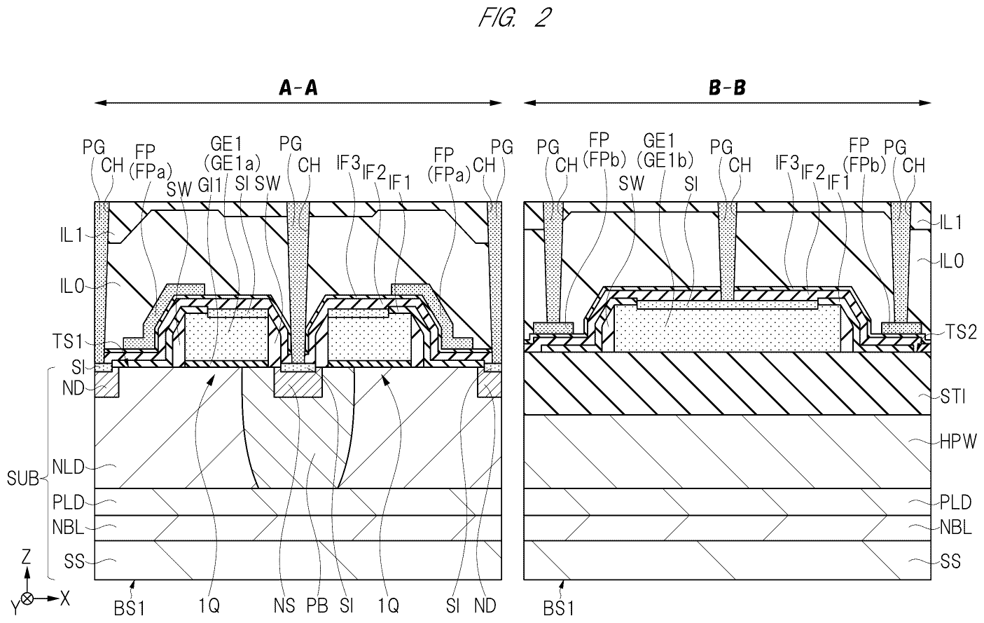

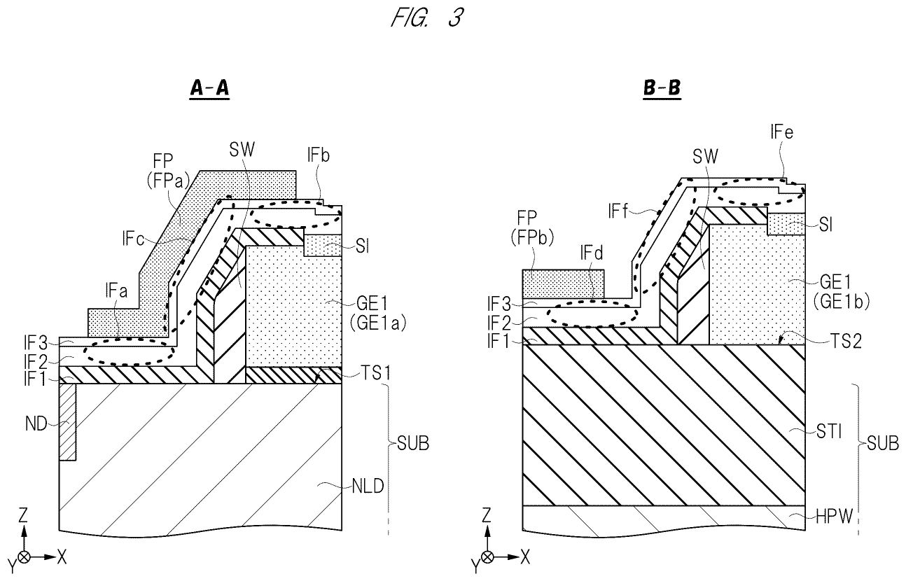

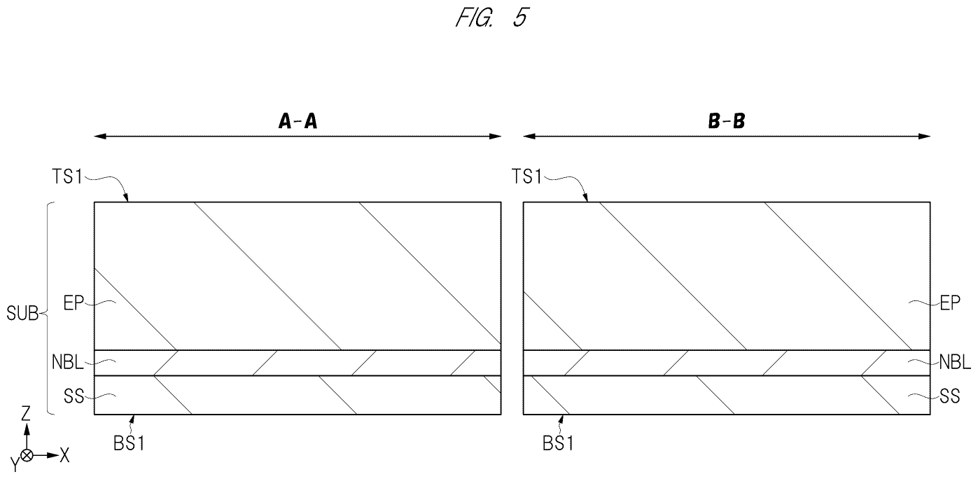

Hereinafter, a semiconductor device according to a first embodiment will be described with reference to FIGS. 1 and 4. The semiconductor device includes a plurality of n-type MISFETs 1Q and a MISFET 2Q. FIG. 1 is a plan view illustrating two MISFETs 1Q. FIG. 2 is a cross-sectional view of the two MISFETs 1Q taken along lines A-A and B-B illustrated in FIG. 1.

As illustrated in FIGS. 1 and 2, each of the plurality of MISFETs 1Q includes a gate insulating film GI1, a gate electrode GE1, a p-type body region (impurity region) PB, a plurality of n-type source regions (impurity regions) NS, a p-type high-concentration diffusion region (impurity region) PR, a p-type well region (impurity region) HPW, an n-type drift region (impurity region) NLD, an n-type drain region (impurity region) ND, and a field plate electrode FP. In addition, an element isolation portion STI is formed in a semiconductor substrate SUB.

The drain region ND extends in the Y direction. In the Y direction, the plurality of source regions NS is separated from each other. The high-concentration diffusion region PR is formed between each of the plurality of source regions NS. The plurality of MISFETs 10 is arranged in line symmetry with the drain region ND and the source region NS as axes. The MISFETs 10 adjacent to each other in the X direction share the drain region ND or the source region NS. The drain region ND is connected to a plug PG for supplying a drain potential. The source region NS and the high-concentration diffusion region PR are connected to a plug PG for supplying a source potential.

In plan view, the gate electrode GE1 and the field plate electrode FP extend in the Y direction. The gate electrode GE1 has an active portion GE1a (A-A cross section) positioned over an upper surface TS1 of the semiconductor substrate SUB and a lead-out portion GE1b (B-B cross section) positioned on an upper surface TS2 of the element isolation portion STI. The field plate electrode FP has an active portion FPa (A-A cross section) positioned over the upper surface TS1 of the semiconductor substrate SUB and a lead-out portion FPb (B-B cross section) positioned over the upper surface TS2 of the element isolation portion STI.

In plan view, the active portion GE1a and the active portion FPa are positioned between the drain region ND and the source region NS and between the drain region ND and the high-concentration diffusion region PR. The active portion GE1a and the active portion FPa of the gate electrode GEL and the field plate electrode FP, respectively, contribute to an operation of the MISFET 1Q.

The lead-out portion GE1b connects the gate electrode GE1 and a plug PG for supplying a gate potential. The lead-out portion FPb connects the field plate electrode FP and a plug PG for supplying a potential. For example, a source potential is supplied to the field plate electrode FP.

The well region HPW is formed between the drift region NLD and the element isolation portion STI in plan view. The well region HPW hardly contributes to the operation of the MISFET 1Q, and the boundary between the active portion FPa and the lead-out portion FPb is positioned on the well region HPW.

As illustrated in the A-A cross section and the B-B cross section of FIG. 2, the semiconductor substrate SUB has the upper surface TS1 and the lower surface BS1, and the element isolation portion STI has the upper surface TS2. The gate electrode GE1 and the field plate electrode FP are formed over the upper surface TS1 of the semiconductor substrate SUB and over the upper surface TS2 of the element isolation portion STI.

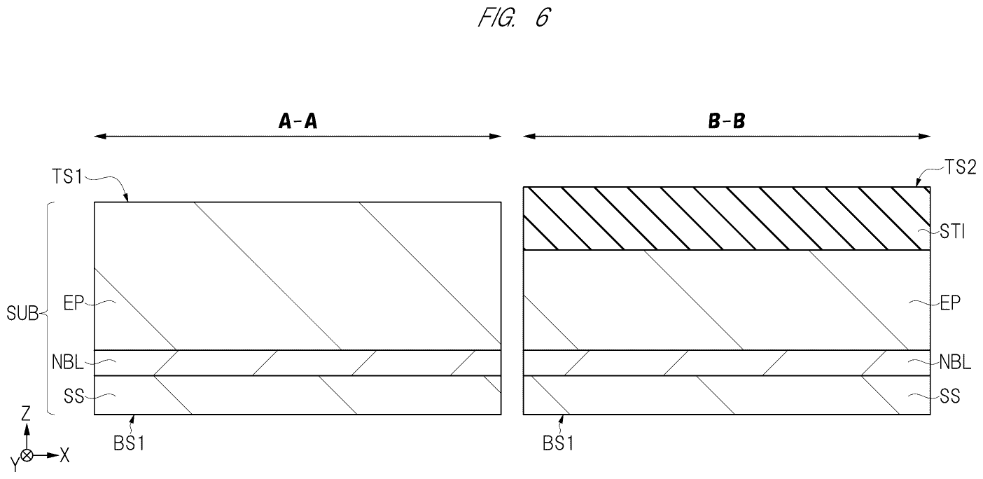

The semiconductor substrate SUB is made of p-type silicon. In the first embodiment, the semiconductor substrate SUB includes, for example, a support substrate SS and a semiconductor layer EP formed on the support substrate SS (see FIG. 5). The support substrate SS is, for example, a p-type silicon substrate. The semiconductor layer EP is, for example, a p-type silicon layer. In the following description, various impurity regions formed in the semiconductor substrate SUB can be specifically formed in the semiconductor layer EP. Note that the semiconductor substrate SUB may be a single-layer silicon substrate.

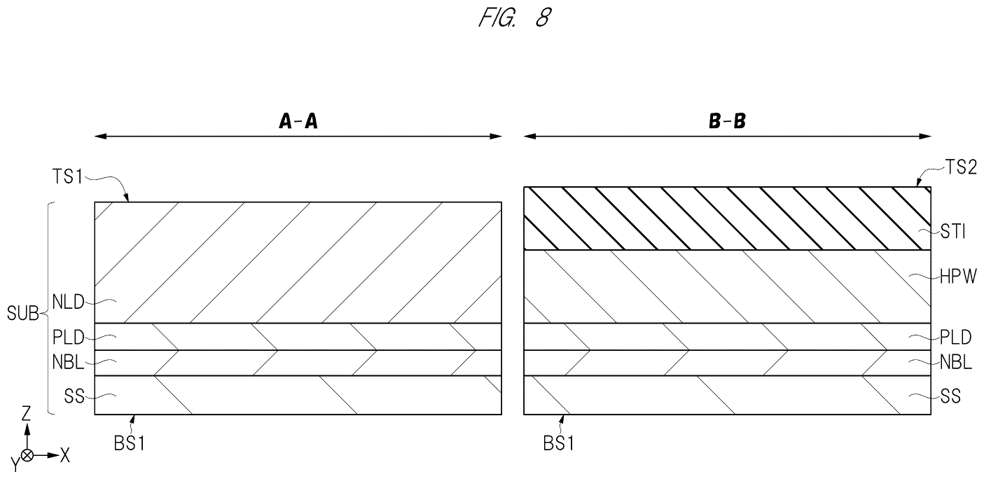

The element isolation portion STI is formed in the semiconductor substrate SUB. The element isolation portion STI includes a trench formed in the semiconductor substrate SUB so as to reach a predetermined depth from the upper surface TS1 of the semiconductor substrate SUB, and an insulating film embedded inside the trench. The insulating film is, for example, a silicon oxide film. Although described in detail later with reference to FIG. 7, in the process of forming the element isolation portion STI, the position of the upper surface TS2 of the element isolation portion STI is higher than the position of the upper surface TS1 of the semiconductor substrate SUB.

In the semiconductor substrate SUB, an n-type drift region NLD, a p-type impurity region PLD, and an n-type buried region NBL are formed. The drift region NLD is formed from the upper surface of the semiconductor substrate SUB to a predetermined depth, and is positioned above the impurity region PLD and the buried region NBL. The impurity region PLD is positioned above the buried region NBL. The impurity region PLD and the buried region NBL are formed at positions deeper than the element isolation portion STI.

The body region PB and the well region HPW are formed in the semiconductor substrate SUB. The body region PB and the well region HPW are formed from the upper surface of the semiconductor substrate SUB to a predetermined depth and formed to a position deeper than the element isolation portion STI. The body region PB and the well region HPW are in contact with the impurity region PLD.

The source region NS is formed in the body region PB. As illustrated in FIG. 1, the high-concentration diffusion region PR is also formed in the body region PB. The drain region ND is formed in the drift region NLD. The drain region ND and the source region NS have a higher impurity concentration than the drift region NLD. The high-concentration diffusion region PR has an impurity concentration higher than the body region PB. A portion of the body region PB positioned between the source region NS and the drain region ND and positioned under the gate electrode GE1 (under the active portion GE1a) functions as a channel region of the MISFET 1Q.

The gate insulating film GIL is formed on the upper surface TS1 of the semiconductor substrate SUB. The gate insulating film GI1 is, for example, a silicon oxide film. As illustrated in the A-A cross section and the B-B cross section, the gate electrode GE1 is formed on the gate insulating film GI1 and on the upper surface TS2 of the element isolation portion STI. The gate electrode GE1 is made of, for example, an n-type polycrystalline silicon film. A sidewall spacer SW is formed on a side surface of the gate electrode GE1. The sidewall spacer SW includes, for example, a silicon oxide film and a silicon nitride film formed on the silicon oxide film.

An insulating film IF1 covers at least a part of an upper surface of the active portion GE1a, the sidewall spacer SW formed on the side surface of the active portion GE1a, and a part of the upper surface TS1 of the semiconductor substrate SUB. In the first embodiment, the insulating film IF1 also covers a part of an upper surface of the lead-out portion GE1b, the sidewall spacer SW formed on the side surface of the lead-out portion GE1b, and a part of the upper surface TS2 of the element isolation portion STI. The insulating film IF1 is, for example, a silicon oxide film.

A silicide film SI is formed on the upper surface of the gate electrode GE1 exposed from the insulating film IF1, on the source region NS, on the drain region ND, and on the high-concentration diffusion region PR. Note that the source region NS and the high-concentration diffusion region PR formed in the body region PB are electrically connected to each other by the same silicide film SI. The silicide film SI is, for example, a cobalt silicide (CoSi₂) film, a nickel silicide (NiSi) film, or a nickel platinum silicide (NiPtSi) film.

An insulating film IF2 is formed over the upper surface TS1 of the semiconductor substrate SUB and over the upper surface TS2 of the element isolation portion STI so as to cover the upper surface of the gate electrode GE1 and the sidewall spacer SW. Note that the insulating film IF2 covers the upper surface of gate electrode GE1 via the insulating film IF1 or the silicide film SI. The insulating film IF2 is, for example, a nitride oxide film. An insulating film IF3 is formed on the insulating film IF2. The insulating film IF3 is made of a material different from that of the insulating film IF2, and is, for example, a silicon oxide film.

The field plate electrode FP is formed on the insulating film IF3. The field plate electrode FP is, for example, a tungsten silicide (WSi₂) film. As a main feature of the first embodiment, the active portion FPa of the field plate electrode FP covers a part of the upper surface of the active portion GE1a of the gate electrode GE1, while the lead-out portion FPb of the field plate electrode FP does not cover the upper surface of the lead-out portion GE1b of the gate electrode GE1. The reason for this will be described in detail later.

The insulating film IF2 mainly plays a role of functioning as an etching stopper film when forming the hole CH and a role of generating tensile stress in the channel region of the MISFET 1Q to increase the mobility of electrons.

The insulating film IF3 mainly plays a role of protecting the insulating film IF2. In a case where the insulating film IF3 is not formed, the insulating film IF2 may be scraped by etching when the field plate electrode FP is formed by patterning. If the thickness of the insulating film IF2 changes and the magnitude of the tensile stress also changes, the characteristics of the MISFET 1Q may fluctuate. For this reason, the insulating film IF3 protects the insulating film IF2. However, in a case where the characteristic fluctuation of the MISFET 1Q is within the allowable range, the insulating film IF3 may not be formed.

An interlayer insulating film IL0 is formed on the insulating film IF3 so as to cover the field plate electrode FP. An interlayer insulating film IL1 is formed on the interlayer insulating film IL0. Note that an upper surface of the interlayer insulating film IL1 is flat.

The interlayer insulating film IL0 is, for example, a phosphorus-doped silicon oxide (phosphorus silicate glass, PSG) film or a boron and phosphorus-doped silicon oxide (boro phospho silicate glass, BPSG) film. The interlayer insulating film IL1 is made of a material different from that of the interlayer insulating film IL0, and is, for example, a silicon oxide film.

A plurality of holes CH is formed in the interlayer insulating film IL1 and in the interlayer insulating film IL0. A plug PG is formed inside each of the plurality of holes CH. The plug PG includes, for example, a barrier metal film and a conductive film formed on the barrier metal film. The barrier metal film includes, for example, a titanium film and a titanium nitride film, and the conductive film is, for example, a tungsten film.

Some of the plurality of holes CH reach the lead-out portion FPb of the field plate electrode FP. Some of the plurality of holes CH that reach the silicide film SI formed on the upper surface of each of the lead-out portion GE1b of the gate electrode GE1, the source region NS, the drain region ND, and the high-concentration diffusion region PR penetrate the interlayer insulating film IL1, the interlayer insulating film IL0, the insulating film IF3, and the insulating film IF2.

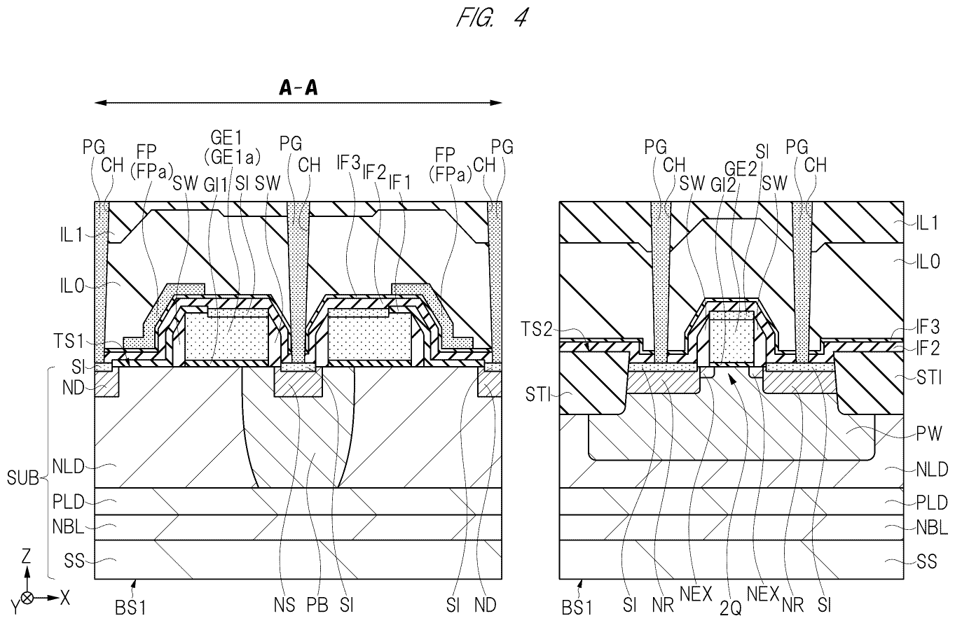

FIG. 3 is an enlarged view of the vicinity of the field plate electrode FP in FIG. 2.

As illustrated in the cross section A-A, the insulating film IF2 and the insulating film IF3 have a flat portion IFa positioned over the upper surface TS1 of the semiconductor substrate SUB, a flat portion IFb positioned over the upper surface of the active portion GE1a of the gate electrode GE1, and a raised portion IFc connecting the flat portion IFa and the flat portion IFb.

The raised portion IFc extends from the upper surface TS1 of the semiconductor substrate SUB toward the upper surface of the active portion GE1a of the gate electrode GE1. In addition, the raised portion IFc is positioned above the flat portion IFa and is positioned on the side surface of the active portion GE1a of the gate electrode GEL via the sidewall spacer SW and the insulating film IF1.

As illustrated in the cross section B-B, the insulating film IF2 and the insulating film IF3 have a flat portion IFd positioned over the upper surface TS2 of the element isolation portion STI, a flat portion IFe positioned over the upper surface of the lead-out portion GE1b of the gate electrode GE1, and a raised portion IFf connecting the flat portion IFd and the flat portion IFe.

The raised portion IFf extends from the upper surface TS2 of the element isolation portion STI toward the upper surface of the lead-out portion GE1b of the gate electrode GE1. In addition, the raised portion IFf is positioned above the flat portion IFd and is positioned on the side surface of the lead-out portion GE1b of the gate electrode GE1 via the sidewall spacer SW and the insulating film IF1.

Hereinafter, the relationship between the field plate electrode FP and the insulating film IF3 is described using the raised portion IFc of the insulating film IF3 and the raised portion IFf of the insulating film IF3. However, as described above, the insulating film IF3 may not be formed. In that case, the description regarding the insulating film IF3, the raised portion IFc of the insulating film IF3, and the raised portion IFf of the insulating film IF3 can be replaced with the description regarding the insulating film IF2, the raised portion IFc of the insulating film IF2, and the raised portion IFf of the insulating film IF2.

Although electric field concentration is likely to occur in the vicinity of the end of the gate electrode GE1 facing the drain region ND, applying the field plate electrode FP can relax the electric field in the vicinity of the end of the gate electrode GE1, thus improving the withstand voltage of the MISFET 1Q.

For this reason, it is preferable that the active portion FPa of the field plate electrode FP is disposed as close as possible to the end of the gate electrode GE1. When the active portion FPa is in contact with the raised portion IFc, the function of the field plate electrode FP can be sufficiently exerted. In the first embodiment, the active portion FPa also covers a part of the insulating film IF3 positioned over the upper surface of the active portion GE1a.

On the other hand, since the lead-out portion FPb of the field plate electrode FP positioned over the element isolation portion STI is formed for the purpose of supplying a potential to the field plate electrode FP, the lead-out portion FPb may be spaced apart from the raised portion IFf. In addition, the lead-out portion FPb does not cover a part of the insulating film IF3 positioned over the upper surface of the lead-out portion GE1b. In other words, a position of the uppermost portion of the lead-out portion FPb is lower than a position of the uppermost portion of the insulating film IF3 positioned over the upper surface of the lead-out portion GE1b.

FIG. 4 is a cross-sectional view illustrating the MISFET 1Q and a MISFET 20 formed in a region different from a region where the MISFET 10 is formed. The MISFET 20 can operate at a higher speed than the MISFET 10 and has a lower withstand voltage than the MISFET 1Q.

As illustrated in FIG. 4, the MISFET 20 includes a gate insulating film GI2, a gate electrode GE2, a p-type well region (impurity region) PW, an n-type extension region (impurity region) NEX, and an n-type high-concentration diffusion region (impurity region) NR.

The well region PW is formed in the semiconductor substrate SUB. The well region PW is formed from the upper surface of the semiconductor substrate SUB to a predetermined depth and is formed to a position deeper than the element isolation portion STI.

The extension region NEX and the high-concentration diffusion region NR are formed in the well region PW. The high-concentration diffusion region NR has an impurity concentration higher than the extension region NEX. The high-concentration diffusion region NR and the extension region NEX constitute a source region or a drain region of the MISFET 2Q.

The gate insulating film GI2 is formed on the upper surface TS1 of the semiconductor substrate SUB. The gate insulating film GI2 is, for example, a silicon oxide film. A gate electrode GE2 is formed on the gate insulating film GI2. The gate electrode GE2 is made of, for example, an n-type polycrystalline silicon film. A sidewall spacer SW is formed on a side surface of the gate electrode GE2. The silicide film SI is formed on an upper surface of each of the gate electrode GE2 and the high-concentration diffusion region NR.

The insulating film IF2 is formed over the upper surface TS1 of the semiconductor substrate SUB and over the upper surface TS2 of the element isolation portion STI so as to cover the upper surface of the gate electrode GE2 and the sidewall spacer SW. Note that the insulating film IF2 covers the upper surface of gate electrode GE2 via the silicide film SI. The insulating film IF3 is formed on the insulating film IF2. The interlayer insulating film IL0 is formed on the insulating film IF3. The interlayer insulating film IL1 is formed on the interlayer insulating film IL0.

The plurality of holes CH is formed in the interlayer insulating film IL1 and in the interlayer insulating film IL0. The plug PG is formed inside each of the plurality of holes CH. Some of the plurality of holes CH that reach the silicide film SI formed on an upper surface of the high-concentration diffusion region NR penetrate the interlayer insulating film IL1, the interlayer insulating film IL0, the insulating film IF3, and the insulating film IF2.

The thickness of the gate insulating film GI2 is smaller than the thickness of the gate insulating film GI1. In addition, the insulating film IF1 and the field plate electrode FP are not formed on the upper surface of the gate electrode GE2. As a result, the height of the MISFET 20 is lower than the height of the MISFET 1Q. In other words, the sum of the thicknesses of the interlayer insulating film IL1 and the interlayer insulating film IL0 formed over the upper surface of the gate electrode GE2 is larger than the sum of the thicknesses of the interlayer insulating film IL1 and the interlayer insulating film IL0 formed on the field plate electrode FP covering the upper surface of the gate electrode GE1.

### <Method of Manufacturing Semiconductor Device>

Manufacturing processes included in a method of manufacturing the semiconductor device according to the first embodiment will be described below with reference to FIGS. 5 to 17.

As illustrated in FIG. 5, the semiconductor substrate SUB is prepared. The semiconductor substrate SUB may be a single-layer p-type silicon substrate, but in the first embodiment, the semiconductor substrate SUB includes the support substrate SS and the semiconductor layer EP. First, the support substrate SS made of p-type silicon is prepared. Next, the semiconductor layer EP, which is a p-type silicon layer, is formed on the support substrate SS by an epitaxial growth method.

Next, the buried region NBL is formed in the semiconductor substrate SUB by a photolithography technique and an ion implantation method. Note that the buried region NBL may be formed in the support substrate SS, and then the semiconductor layer EP may be formed on the support substrate SS.

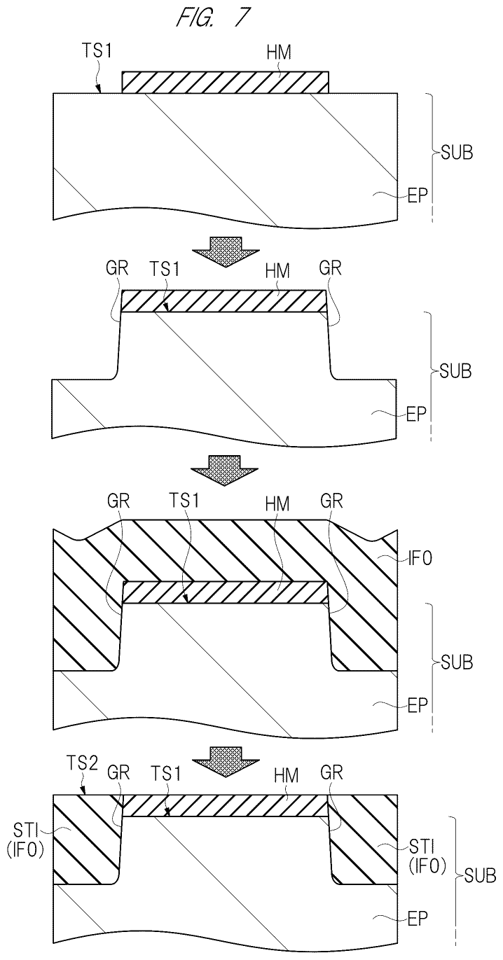

As illustrated in FIG. 6, the element isolation portion STI is formed in the semiconductor substrate SUB so as to reach a predetermined depth from the upper surface TS1 of the semiconductor substrate SUB. Hereinafter, a detailed manufacturing process for forming the element isolation portion STI will be described with reference to FIG. 7.

As illustrated in FIG. 7, first, an insulating film such as a silicon nitride film is formed on the upper surface TS1 of the semiconductor substrate SUB by, for example, a film forming process using a CVD method. Next, the insulating film is patterned to form a hard mask HM. Next, an anisotropic etching process is performed using the hard mask HM as a mask to form a trench GR in the semiconductor substrate SUB.

Next, the insulating film IF0 is formed on the upper surface TS1 of the semiconductor substrate SUB so as to be embedded in the inside of the trench GR. The insulating film IF0 is, for example, a silicon oxide film. Next, the insulating film IF0 positioned outside the trench GR is removed by a polishing process using the CMP method so as to leave the insulating film IF0 embedded inside the trench GR. In this manner, the element isolation portion STI including the trench GR and the insulating film IF0 is formed.

Thereafter, the hard mask HM is selectively removed by, for example, an isotropic etching process to expose the upper surface TS1 of the semiconductor substrate SUB. At this point, the position of the upper surface TS2 of the element isolation portion STI is higher than the position of the upper surface TS1 of the semiconductor substrate SUB.

As illustrated in FIG. 8, the impurity region PLD, the drift region NLD, and the well region HPW are sequentially formed in the semiconductor substrate SUB by the photolithography technique and the ion implantation method. Any one of them may be formed first.

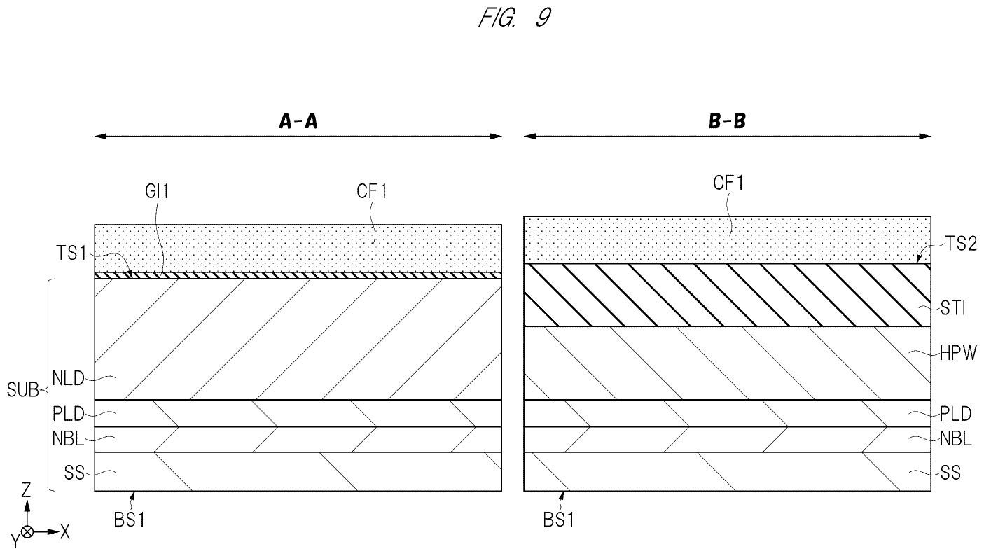

As illustrated in FIG. 9, the gate insulating film GI1 and a conductive film CF1 are formed. First, the gate insulating film GI1 is formed on the upper surface TS1 of the semiconductor substrate SUB by, for example, thermal oxidation treatment. Next, the conductive film CF1 is formed on the gate insulating film GI1 and on the upper surface TS2 of the element isolation portion STI by, for example, the film forming process using the CVD method. The conductive film CF1 is, for example, a polycrystalline silicon film into which an n-type impurity is introduced.

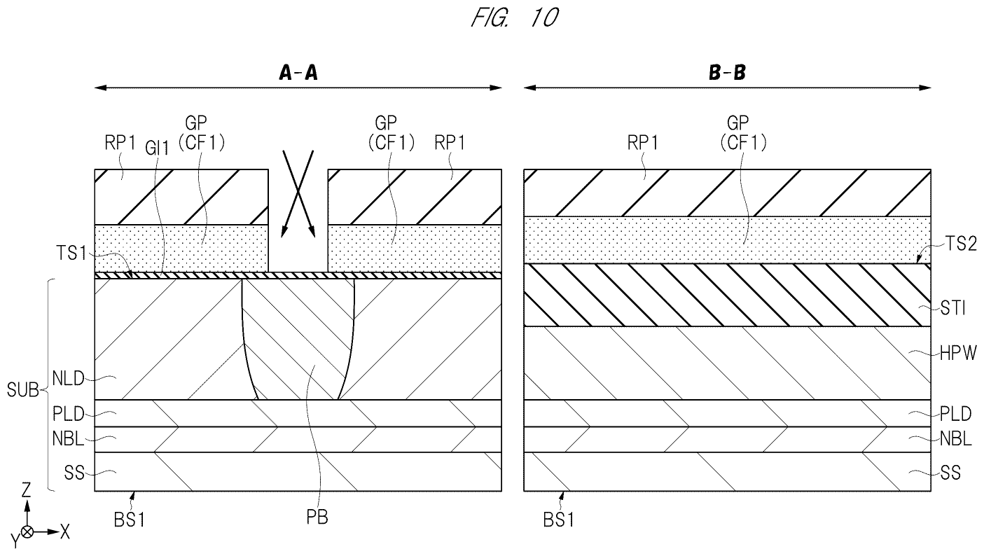

As illustrated in FIG. 10, a gate pattern GP and the body region PB are formed. First, a resist pattern RP1 is formed on the conductive film CF1. The resist pattern RP1 has an opening that opens a part of the conductive film CF1 positioned on the gate insulating film GI1. Next, the anisotropic etching process is performed using the resist pattern RP1 as a mask to selectively remove the conductive film CF1 exposed from the resist pattern RP1 and form a plurality of gate patterns GP from the conductive film CF1.

Next, oblique ion implantation is performed using the resist pattern RP1 as a mask to form the body region PB in the drift region NLD. In this oblique ion implantation, ions are implanted from a direction inclined at an angle of, for example, 20 degrees or more and 45 degrees or less with respect to a direction (Z direction) perpendicular to the upper surface TS1 of the semiconductor substrate SUB. The body region PB is also formed in a portion of the semiconductor substrate SUB positioned between the plurality of gate patterns GP in plan view and in a part of the semiconductor substrate SUB positioned under each gate pattern GP. Thereafter, the resist pattern RP1 is removed by an ashing process.

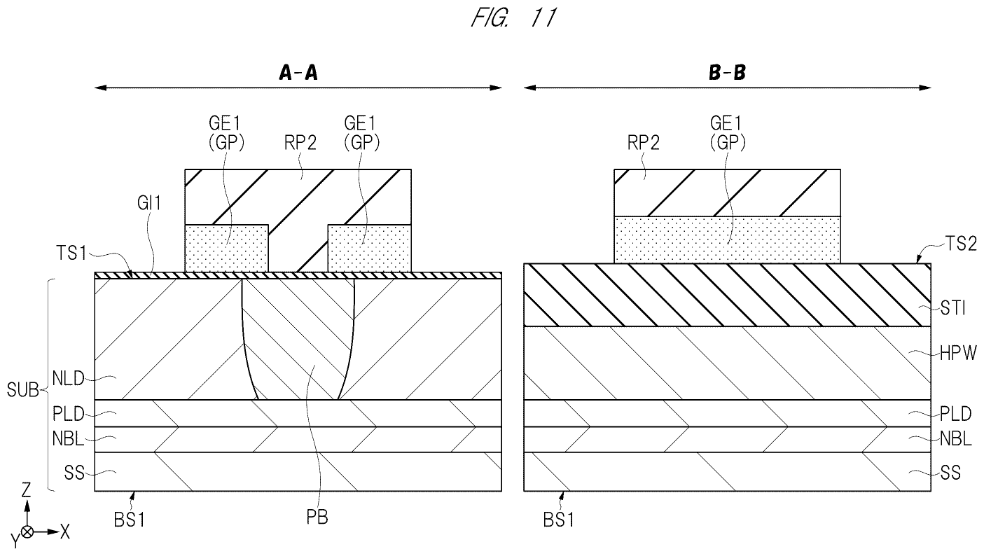

As illustrated in FIG. 11, the gate electrode GE1 is formed. First, a resist pattern RP2 covering the body region PB and a part of the gate pattern GP is formed. Next, the anisotropic etching process is performed using the resist pattern RP2 as a mask to selectively remove the gate pattern GP exposed from the resist pattern RP2 and form the gate electrode GE1 from the gate pattern GP. Thereafter, the resist pattern RP2 is removed by the ashing process.

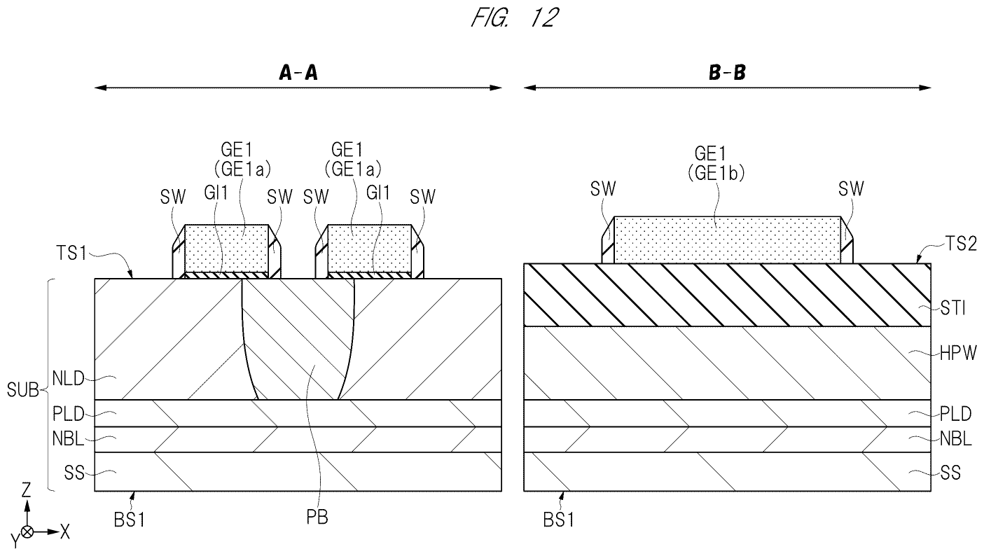

As illustrated in FIG. 12, the sidewall spacer SW is formed on the side surface of the gate electrode GE1. First, a stacked film including, for example, a silicon oxide film and a silicon nitride film is formed on the upper surface TS1 of the semiconductor substrate SUB by, for example, the film forming process using the CVD method so as to cover the gate electrode GE1. Next, the anisotropic etching process is performed on the stacked film to form the sidewall spacer SW from the stacked film left on the side surface of the gate electrode GE1. In addition, the gate insulating film GI1 exposed from the gate electrode GE1 is also removed by the anisotropic etching process.

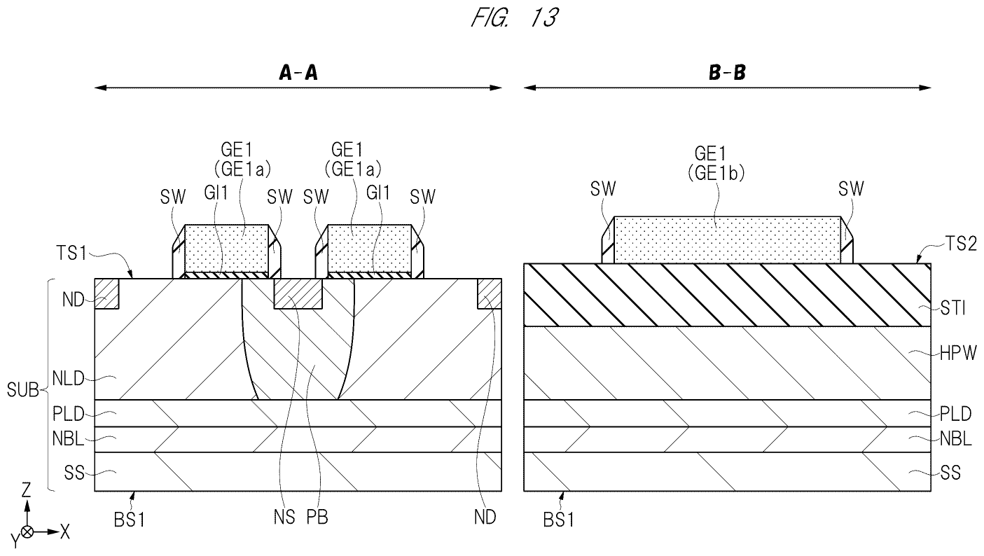

As illustrated in FIG. 13, first, the source region NS is formed in the body region PB, and the drain region ND is formed in the drift region NLD by the photolithography technique and the ion implantation method. Next, although not illustrated, the high-concentration diffusion region PR is formed in the body region PB by the photolithography technique and the ion implantation method.

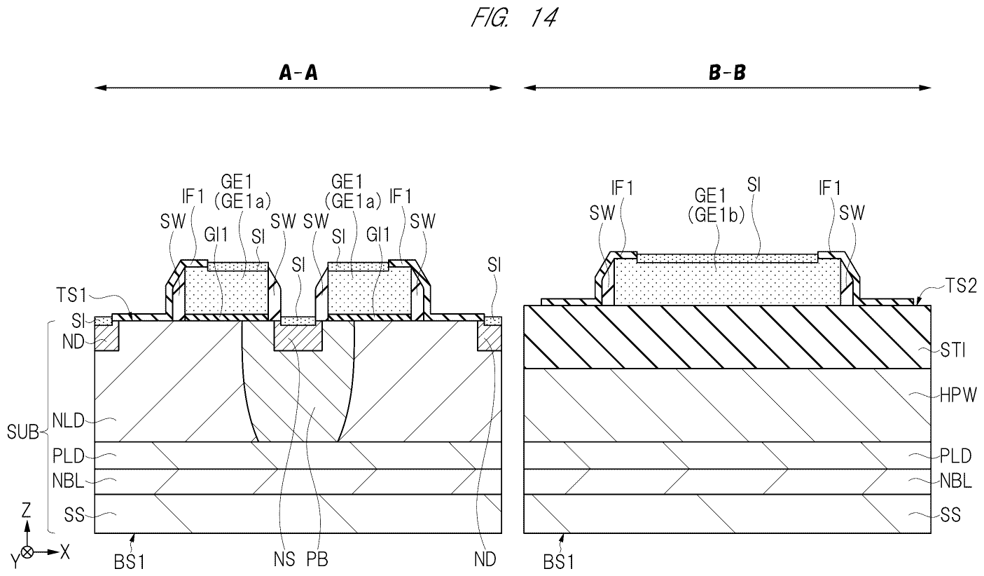

As illustrated in FIG. 14, the insulating film IF1 and the silicide film SI are formed. First, the insulating film IF1 is formed over the upper surface TS1 of the semiconductor substrate SUB and over the upper surface TS2 of the element isolation portion STI by, for example, the film forming process using the CVD method, so as to cover the upper surface of the gate electrode GE1 and the sidewall spacer SW.

Next, the insulating film IF1 is patterned so as to cover at least a part of the upper surface of the active portion GE1a, the sidewall spacer SW positioned on the side surface of the active portion GE1a, and a part of the upper surface TS1 of the semiconductor substrate SUB. In the first embodiment, the insulating film IF1 is patterned so as to cover a part of the upper surface of the lead-out portion GE1b, the sidewall spacer SW positioned on the side surface of the lead-out portion GE1b, and a part of the upper surface TS2 of the element isolation portion STI.

Next, the silicide film SI is formed on the upper surface of the gate electrode GEL exposed from the insulating film IF1 and on the upper surface TS1 of the semiconductor substrate SUB by a salicide technique. The silicide film SI is formed on the upper surface of each of the drain region ND, the source region NS, and the high-concentration diffusion region PR.

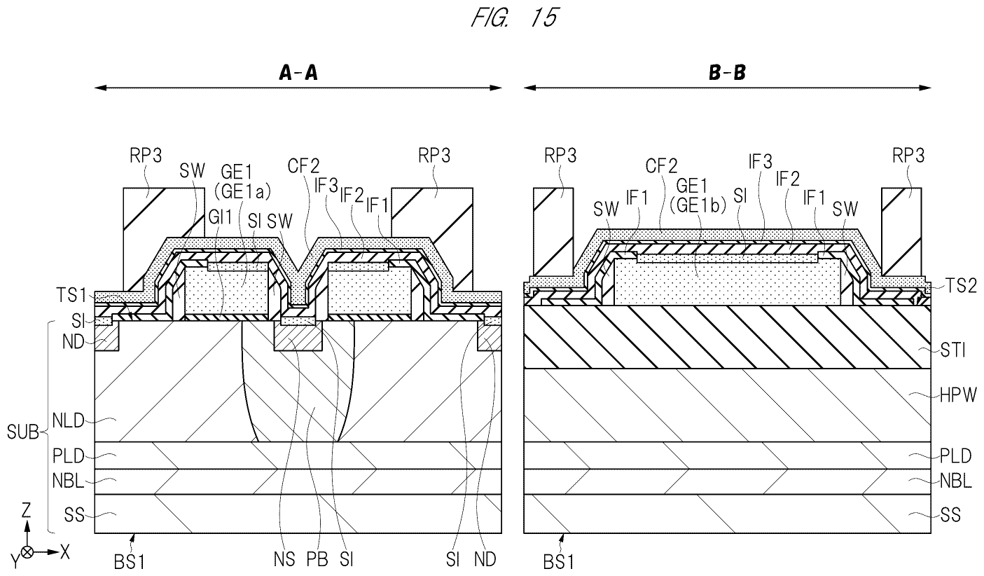

As illustrated in FIG. 15, the insulating film IF2, the insulating film IF3, and the conductive film CF2 are formed. First, the insulating film IF2 is formed over the upper surface TS1 of the semiconductor substrate SUB and over the upper surface TS2 of the element isolation portion STI by, for example, the film forming process using the CVD method, so as to cover the upper surface of the gate electrode GEL and the sidewall spacer SW. Next, the insulating film IF3 is formed on the insulating film IF2 by, for example, the film forming process using the CVD method.

Next, the conductive film CF2 is formed on the insulating film IF3 by, for example, the film forming process using the CVD method. The conductive film CF2 is, for example, a tungsten silicide film. Next, a resist pattern RP3 is formed on the conductive film CF2. The resist pattern RP3 has an opening that opens the drain region ND, a part of the active portion GE1a, the source region NS, and the lead-out portion GE1b.

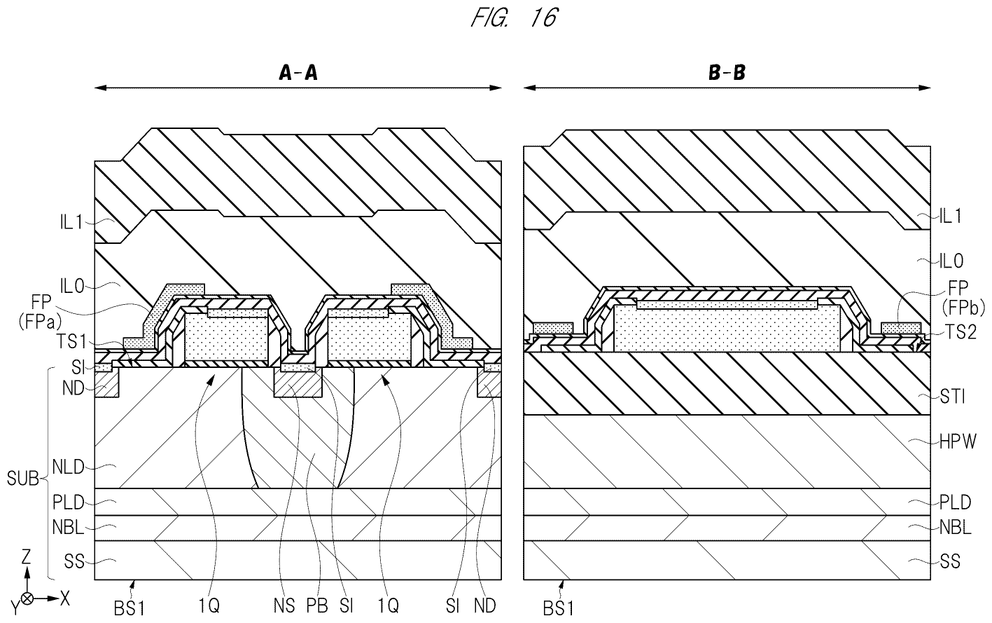

As illustrated in FIG. 16, the field plate electrode FP, the interlayer insulating film IL0, and the interlayer insulating film IL1 are formed. First, the anisotropic etching process is performed using the resist pattern RP3 as a mask to pattern the conductive film CF2 and form the field plate electrode FP. Next, the resist pattern RP3 is removed by the ashing process.

In the first embodiment, the active portion FPa is in contact with the raised portion IFc and covers a part of the insulating film IF3 positioned over the upper surface of the active portion GE1a. In addition, the lead-out portion FPb is spaced apart from the raised portion IFf, and a position of the uppermost portion of the lead-out portion FPb is lower than a position of the uppermost portion of the insulating film IF3 positioned over the upper surface of the lead-out portion GE1b.

Next, the interlayer insulating film IL0 is formed on the insulating film IF3 so as to cover the field plate electrode FP by the film forming process using the CVD method. Next, the interlayer insulating film IL1 is formed on the interlayer insulating film IL0 by the film forming process using a plasma CVD method. The interlayer insulating film IL0 is used to be satisfactorily embedded in a gap between the plurality of gate electrodes GE1. That is, the embeddability of the interlayer insulating film IL0 is higher than the embeddability of the interlayer insulating film IL1.

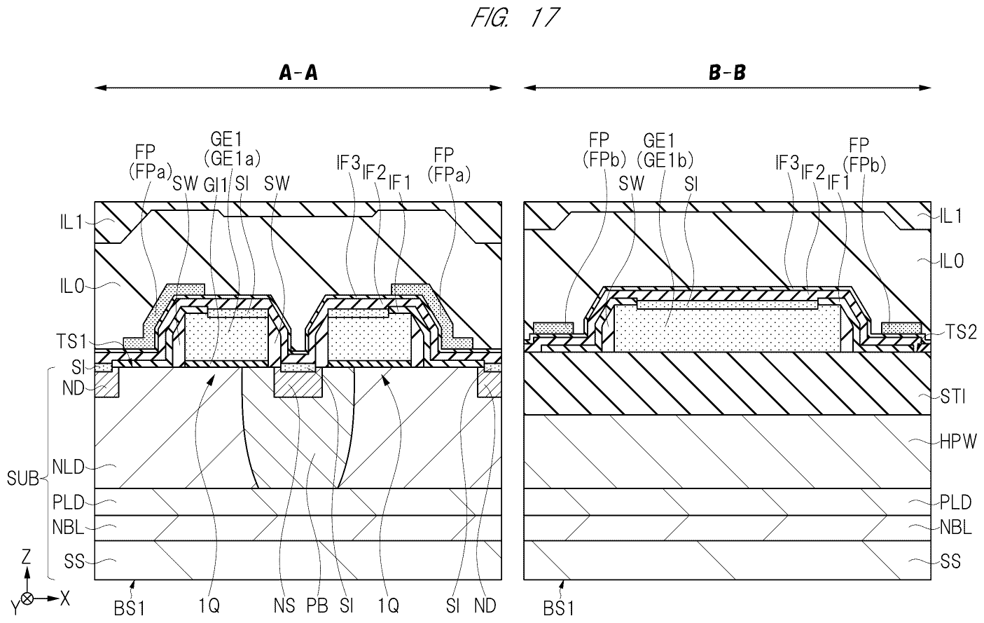

As illustrated in FIG. 17, first, a planarization process using the CMP method is performed on the interlayer insulating film IL1. At this point, the interlayer insulating film IL0 positioned over the upper surface of the active portion GE1a and the upper surface of the lead-out portion GE1b is covered with the interlayer insulating film IL1.

Next, cleaning treatment is performed on the upper surface of the interlayer insulating film IL1. In this cleaning treatment, at least one of an aqueous solution containing hydrofluoric acid and hydrogen peroxide water and an aqueous solution containing ammonia and hydrogen peroxide water is used. The etching rate of the interlayer insulating film IL0 for the cleaning treatment is higher than the etching rate of the interlayer insulating film IL1 for the cleaning treatment.

Thereafter, the structure illustrated in FIG. 2 is obtained through the following manufacturing steps. First, the plurality of holes CH are formed in the interlayer insulating film IL1 and in the interlayer insulating film IL0 by the photolithography technique and the anisotropic etching process. Next, the plug PG is formed inside each of the plurality of holes CH.

In order to form the plug PG, first, for example, a titanium film is formed inside the plurality of holes CH and on the interlayer insulating film IL1 by, for example, a film forming process using a sputtering method. Next, for example, a titanium nitride film is formed on the titanium film by, for example, the film forming process using the CVD method. The titanium film and the titanium nitride film are a barrier metal film. Next, for example, a tungsten film is formed on the barrier metal film by, for example, the film forming process using the CVD method so as to fill the inside of the plurality of holes CH. Next, the tungsten film and the barrier metal film formed outside the plurality of holes CH are removed by, for example, the polishing process using the CMP method.

### <Problems of Examination Example and Main Features of First Embodiment>

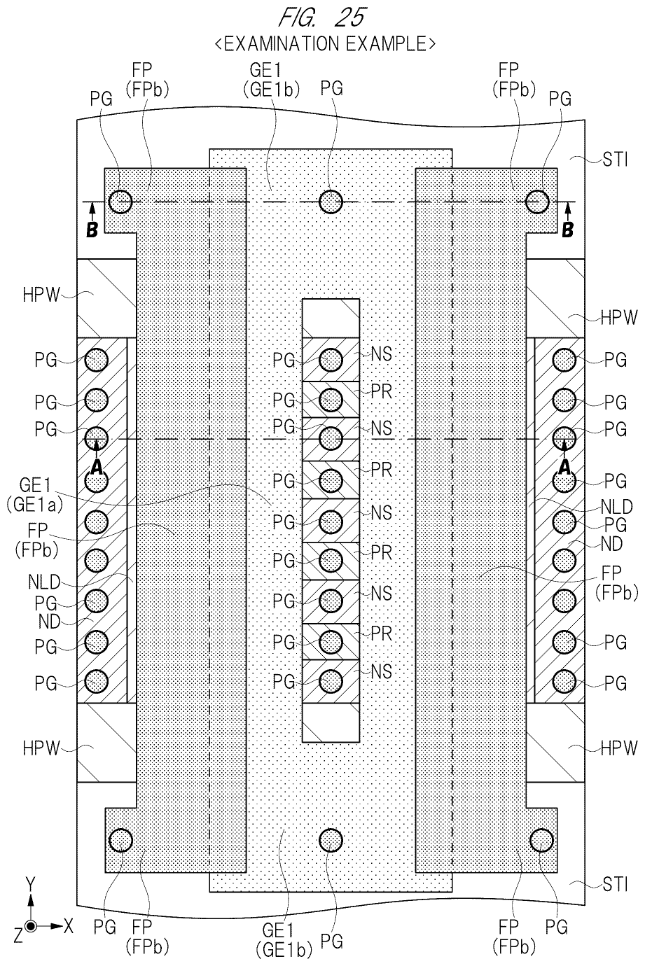

Hereinafter, a semiconductor device of an examination example studied by the inventor of the present application will be described with reference to FIGS. 25 to 27.

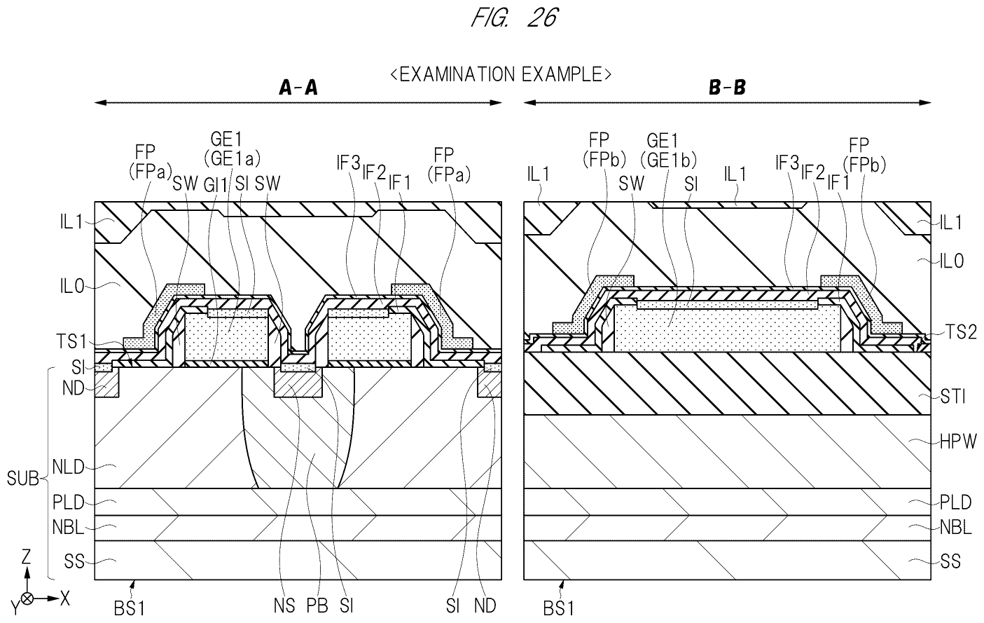

In the first embodiment, the lead-out portion FPb of the field plate electrode FP is not formed over the upper surface of the lead-out portion GE1b of the gate electrode GE1. On the other hand, in the examination example, as illustrated in FIGS. 25 and 26, the lead-out portion FPb is formed over the upper surface of the lead-out portion GE1b.

As describe above, in the process of forming the element isolation portion STI, the position of the upper surface TS2 of the element isolation portion STI is higher than the position of the upper surface TS1 of the semiconductor substrate SUB. That is, the position of the upper surface of the lead-out portion GE1b of the gate electrode GE1 is higher than the upper surface of the active portion GE1a of the gate electrode GE1. Therefore, the sum of the thicknesses of the interlayer insulating film IL1 and the interlayer insulating film IL0 formed on the lead-out portion FPb covering the upper surface of the lead-out portion GE1b is smaller than the sum of the thicknesses of the interlayer insulating film IL1 and the interlayer insulating film IL0 formed on the active portion FPa covering the upper surface of the active portion GE1a.

As a result, when the planarization process using the CMP method is performed on the interlayer insulating film IL1, the interlayer insulating film IL1 positioned over the lead-out portion FPb is not left, the interlayer insulating film IL0 is exposed, and the planarization process is more likely to be also performed on the interlayer insulating film IL0. In addition, in the planarization process using the CMP method, dent marks or linear marks called micro scratches are generated in the interlayer insulating film IL0 due to particles or the like contained in the slurry.

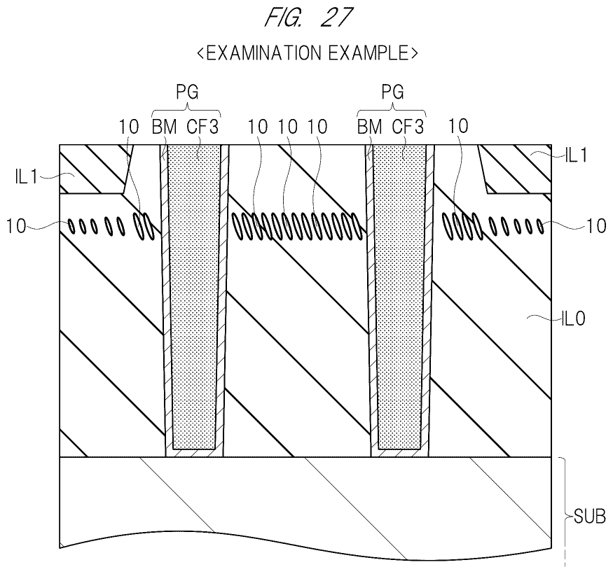

FIG. 27 is a cross-sectional view for explaining a defect caused by a micro scratch 10. After the planarization process, cleaning treatment is performed to clean the upper surface of the interlayer insulating film IL1. Here, if the interlayer insulating film IL0 is exposed, an aqueous solution used for the cleaning treatment penetrates into the interlayer insulating film IL0. In the cleaning treatment, at least one of an aqueous solution containing hydrofluoric acid and hydrogen peroxide water and an aqueous solution containing ammonia and hydrogen peroxide water is used.

Here, the etching rate of the interlayer insulating film IL0 for the cleaning treatment is higher than the etching rate of the interlayer insulating film IL1 for the cleaning treatment. Therefore, due to the cleaning treatment, the micro scratch 10 generated in the interlayer insulating film IL0 is enlarged, and the micro scratches 10 are easily connected to each other.

Thereafter, when the plug PG is formed in the interlayer insulating film IL0, the barrier metal film BM is formed, and then a conductive film CF3 such as a tungsten film is formed. In order to form the barrier metal film BM, first, for example, the titanium film is formed by the film forming process using the sputtering method. Next, the titanium nitride film is formed on the titanium film by, for example, the film forming process using the CVD method. If the film forming process using this CVD method is performed in a state where the micro scratches 10 are connected to each other, the titanium nitride film may be formed in the micro scratch 10 and a leak path may be formed between two plugs PG adjacent to each other.

In the first embodiment, as illustrated in FIGS. 2 and 3, the lead-out portion FPb does not cover a part of the insulating film IF3 positioned over the upper surface of the lead-out portion GE1b and is spaced apart from the raised portion IFf.

Therefore, the interlayer insulating film IL0 is not exposed not only at a portion over the upper surface of the active portion GE1a but also at a portion over the upper surface of the lead-out portion GE1b, and is covered with the interlayer insulating film IL1. As a result, it is possible to suppress the micro scratches 10 from being connected to each other by cleaning treatment and the leak path from being formed, thus improving the reliability of the semiconductor device. At the same time, since the active portion FPa is in contact with the raised portion IFc, the function of the field plate electrode FP can be sufficiently exerted.

### Second Embodiment

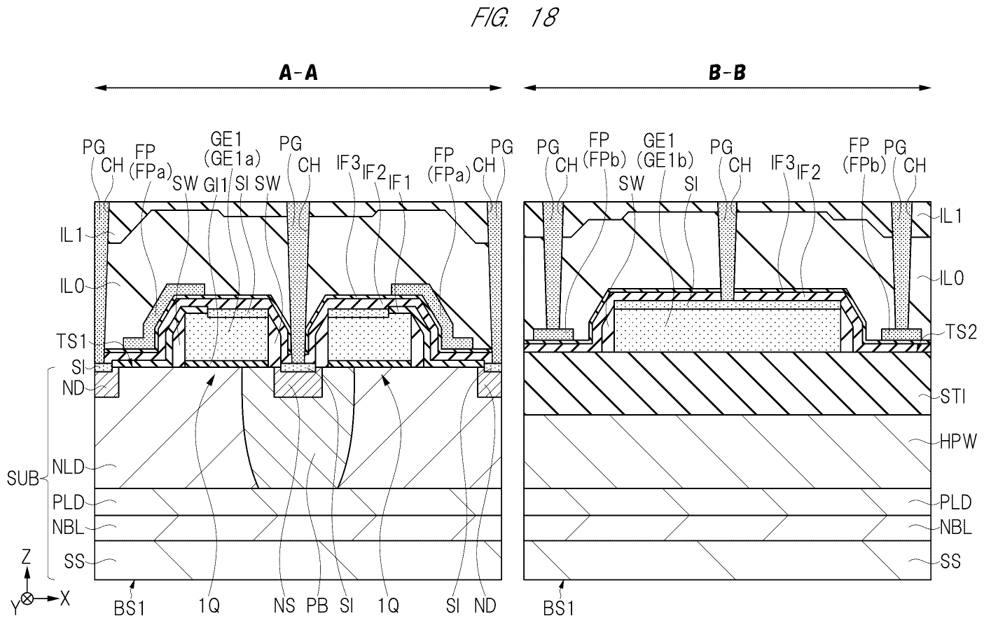

Hereinafter, a semiconductor device and a method of manufacturing the semiconductor device according to a second embodiment will be described with reference to FIG. 18. In the following description, differences from the first embodiment will be mainly described, and description of points overlapping with the first embodiment will be omitted.

In the second embodiment, the insulating film IF1 used to selectively form the silicide film SI is not formed on the upper surface of the lead-out portion GE1b of the gate electrode GE1. In addition, the insulating film IF1 is not formed between the lead-out portion FPb of the field plate electrode FP and the upper surface TS2 of the element isolation portion STI.

Therefore, the thickness of the interlayer insulating film IL1 can be increased at a portion immediately above where the insulating film IF1 is formed in the first embodiment. As a result, in the second embodiment, the interlayer insulating film IL0 is further less likely to be exposed at a portion over the upper surface of the lead-out portion GE1b as compared with the first embodiment.

In order to obtain the structure of the second embodiment, in the manufacturing step in FIG. 14, the insulating film IF1 may be patterned so as not to leave the insulating film IF1 on a part of the upper surface of the lead-out portion GE1b, the sidewall spacer SW positioned on the side surface of the lead-out portion GE1b, and a part of the upper surface TS2 of the element isolation portion STI. The insulating film IF1 is patterned so as to remove at least the insulating film IF1 covering the upper surface of the lead-out portion GE1b.

### Third Embodiment

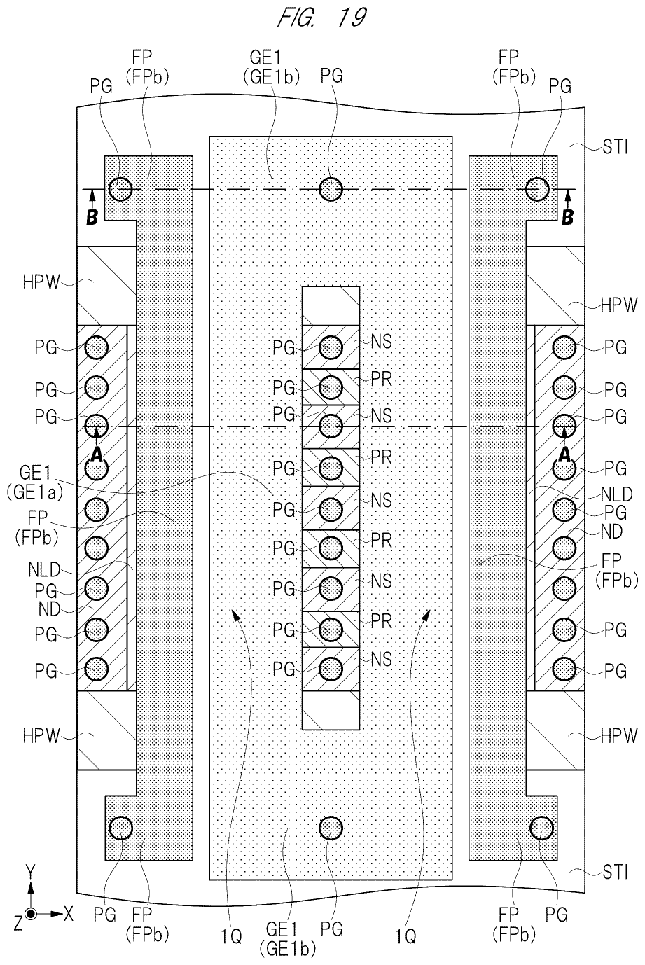

Hereinafter, a semiconductor device and a method of manufacturing the semiconductor device according to a third embodiment will be described with reference to FIGS. 19 to 21. In the following description, differences from the first embodiment will be mainly described, and description of points overlapping with the first embodiment will be omitted.

In the first embodiment, since the lead-out portion FPb of the field plate electrode FP is spaced apart from the raised portion IFf, the lead-out portion FPb does not cover a part of the insulating film IF3 positioned over the upper surface of the lead-out portion GE1b of the gate electrode GE1.

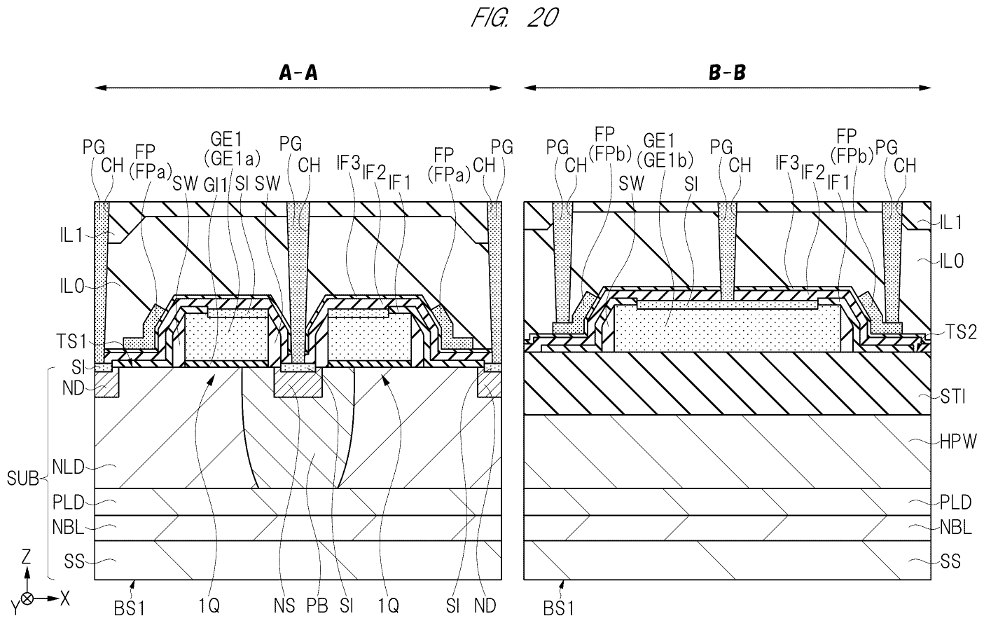

In the third embodiment, as illustrated in FIGS. 19 and 20, the lead-out portion FPb is in contact with the raised portion IFf, but a position of the uppermost portion of the lead-out portion FPb is lower than a position of the uppermost portion of the insulating film IF3 positioned over the upper surface of the lead-out portion GE1b. In addition, the active portion FPa of the field plate electrode FP is in contact with the raised portion IFc, and a position of the uppermost portion of the active portion FPa is lower than a position of the uppermost portion of the insulating film IF3 positioned over the upper surface of the active portion GE1a of the gate electrode GE1.

Also in the third embodiment, similarly to the first embodiment, the function of the field plate electrode FP can be maintained, while the interlayer insulating film IL0 can be suppressed from being exposed at a portion over the upper surface of the lead-out portion GE1b.

In addition, the active portion FPa does not cover a part of the insulating film IF3 positioned over the upper surface of the active portion GE1a. Therefore, in the third embodiment, the interlayer insulating film IL0 is further less likely to be exposed at a portion over the upper surface of the active portion GE1a as compared with the first embodiment.

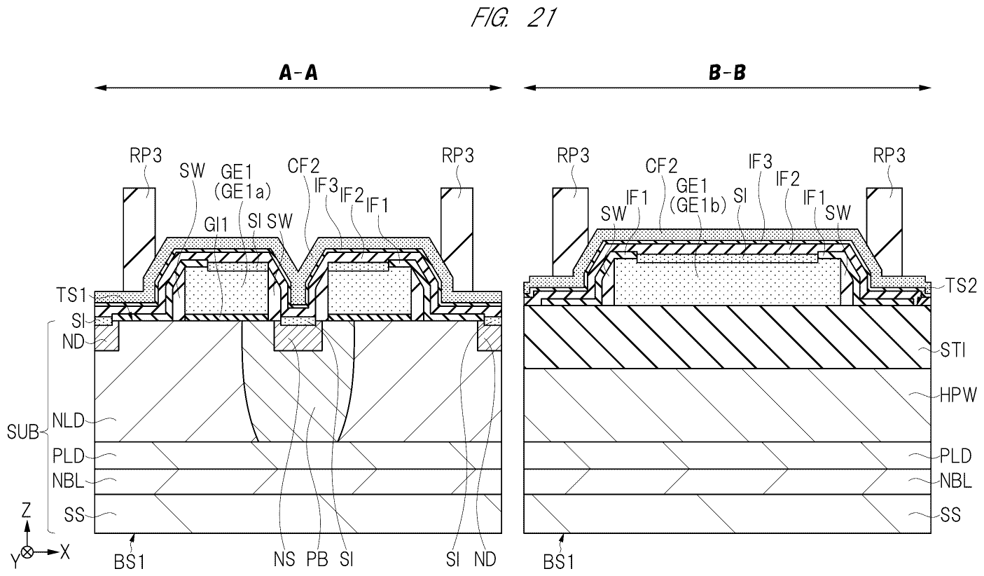

In order to obtain the structure of the third embodiment, as illustrated in FIG. 21, the position of the opening of the resist pattern RP3 used in the manufacturing process of FIG. 15 is changed. The resist pattern RP3 of the third embodiment has an opening that opens the drain region ND, the active portion GE1a, the source region NS, and the lead-out portion GE1b. The end of the opening is set in the middle of the raised portion IFc and in the middle of the raised portion IFf. The active portion FPa and the lead-out portion FPb are formed by patterning the conductive film CF2 using the resist pattern RP3 of the third embodiment.

Note that the technique disclosed in the third embodiment can be applied in combination with the technique disclosed in the second embodiment. That is, in the third embodiment, the insulating film IF1 may not be formed on the upper surface of the lead-out portion GE1b of the gate electrode GE1, and the insulating film IF1 may not be formed between the lead-out portion FPb of the field plate electrode FP and the upper surface TS2 of the element isolation portion STI.

### Fourth Embodiment

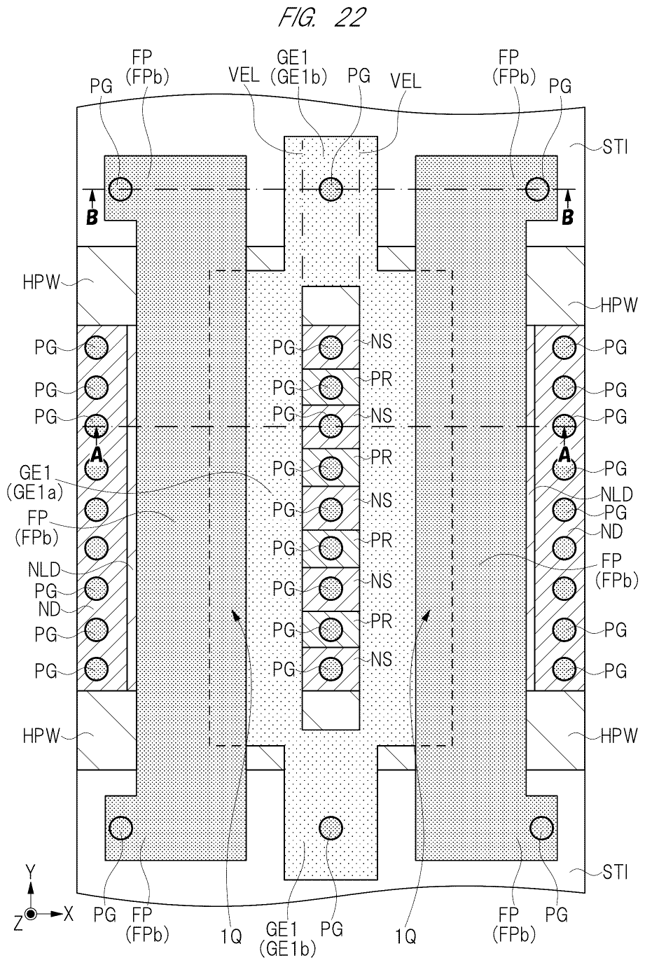

Hereinafter, a semiconductor device and a method of manufacturing the semiconductor device according to a fourth embodiment will be described with reference to FIGS. 22 to 24. In the following description, differences from the first embodiment will be mainly described, and description of points overlapping with the first embodiment will be omitted.

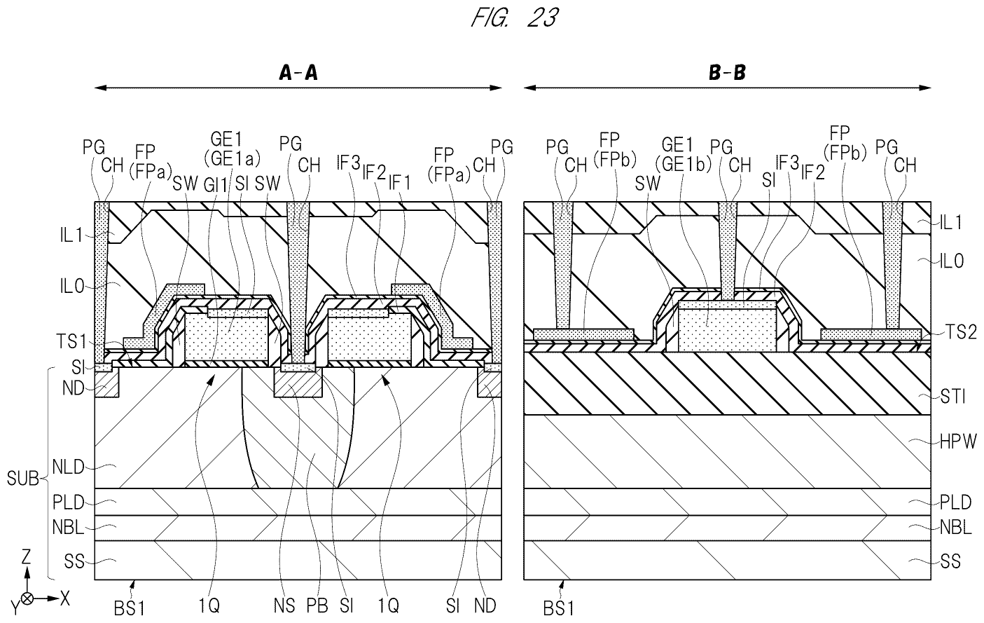

In the fourth embodiment, as illustrated in FIGS. 22 and 23, the side surface of the lead-out portion GE1b is recessed from the side surface of the active portion GE1a in the X direction. In other words, in the X direction, the width of the lead-out portion GE1b is smaller than the sum of the width of each of the two active portions GE1a and the distance between the two active portions GE1a adjacent to each other via the source region NS1. Further in other words, in the X direction, the distance from the side surface of the lead-out portion GE1b to a virtual extension line VEL is smaller than the width of the active portion GE1a. As illustrated in FIG. 22, the virtual extension line VEL extends the side surface of the active portion GE1a facing the source region NS1 in the Y direction.

Therefore, the lead-out portion FPb is spaced apart from the raised portion IFf, and does not cover a part of insulating film IF3 positioned over the upper surface of the lead-out portion GE1b. In addition, a position of the uppermost portion of the lead-out portion FPb is lower than a position of the uppermost portion of the insulating film IF3 positioned over the upper surface of the lead-out portion GE1b.

Also in the fourth embodiment, similarly to the first embodiment, the interlayer insulating film IL0 is less likely to be exposed at a portion over the upper surface of the lead-out portion GE1b.

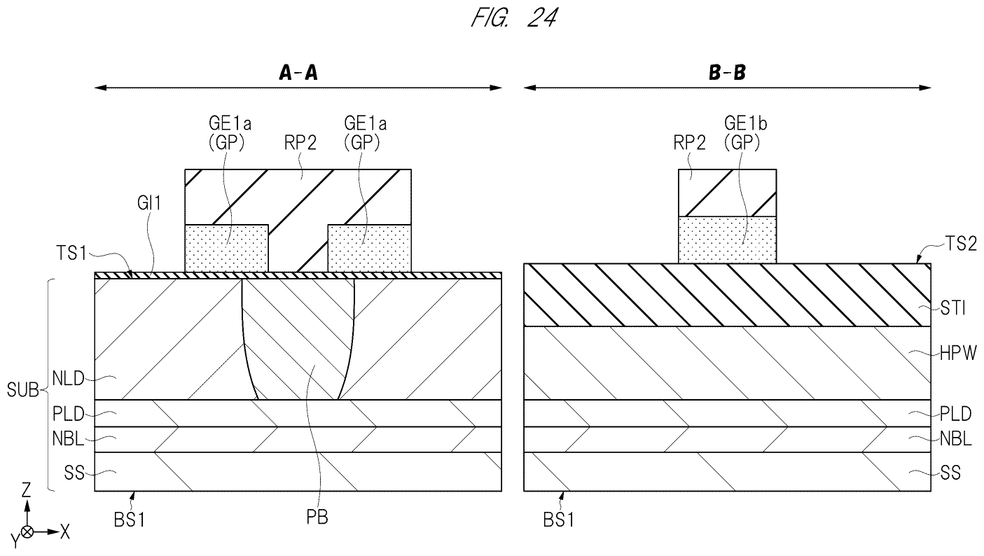

In order to obtain the structure of the fourth embodiment, as illustrated in FIG. 24, the position of the opening of the resist pattern RP2 used in the manufacturing process of FIG. 11 is changed. The resist pattern RP2 of the fourth embodiment has an opening such that the width of the gate pattern GP left on the element isolation portion STI is small as compared with the resist pattern RP2 of the first embodiment. The lead-out portion GE1b is formed by patterning the gate pattern GP using the resist pattern RP2 of the fourth embodiment.

Note that the technique disclosed in the fourth embodiment can be applied in combination with the techniques disclosed in the second embodiment and third embodiment. That is, in the fourth embodiment, the insulating film IF1 may not be formed on the upper surface of the lead-out portion GE1b of the gate electrode GE1, and the insulating film IF1 may not be formed between the lead-out portion FPb of the field plate electrode FP and the upper surface TS2 of the element isolation portion STI. Furthermore, in the fourth embodiment, a position of the uppermost portion of the lead-out portion FPb may be lower than a position of the uppermost portion of the insulating film IF3 positioned over the upper surface of the lead-out portion GE1b, and a position of the uppermost portion of the active portion FPa may be lower than a position of the uppermost portion of the insulating film IF3 positioned over the upper surface of the active portion GE1a of the gate electrode GE1.

Although the present invention has been specifically described based on the above embodiments, the present invention is not limited to these embodiments, and various modifications may be made without departing from the gist of the present invention.

What is claimed is:

1. A semiconductor device comprising:
a semiconductor substrate having an upper surface;
an element isolation portion having a predetermined depth from the upper surface of the semiconductor substrate and formed in the semiconductor substrate;
a gate insulating film formed on the upper surface of the semiconductor substrate;
a gate electrode formed on the gate insulating film and on an upper surface of the element isolation portion;
a sidewall spacer formed on a side surface of the gate electrode;
a first insulating film covering an upper surface of the gate electrode and the sidewall spacer, the first insulating film being formed over the upper surface of the semiconductor substrate and over the upper surface of the element isolation portion; and
a field plate electrode formed on the first insulating film,
wherein the gate electrode includes:
a first portion positioned over the upper surface of the semiconductor substrate; and
a second portion positioned over the upper surface of the element isolation portion,
wherein the first insulating film includes:
a third portion positioned over the upper surface of the semiconductor substrate;
a fourth portion positioned above the third portion and positioned on the side surface of the first portion of the gate electrode via the sidewall spacer;
a fifth portion positioned over the upper surface of the element isolation portion; and
a sixth portion positioned above the fifth portion and positioned on the side surface of the second portion of the gate electrode via the sidewall spacer,
wherein the field plate electrode includes:
a seventh portion positioned over the upper surface of the semiconductor substrate; and
an eighth portion positioned over the upper surface of the element isolation portion,
wherein a position of the upper surface of the second portion of the gate electrode is higher than a position of the upper surface of the first portion of the gate electrode,
wherein the seventh portion of the field plate electrode is in contact with the fourth portion of the first insulating film, and
wherein a position of an uppermost portion of the eighth portion of the field plate electrode is lower than a position of an uppermost portion of the first insulating film positioned over the upper surface of the second portion of the gate electrode.

2. The semiconductor device according to claim 1,
wherein a position of the upper surface of the element isolation portion is higher than a position of the upper surface of the semiconductor substrate.

3. The semiconductor device according to claim 1,
wherein the seventh portion of the field plate electrode covers a part of the first insulating film positioned over the upper surface of the first portion of the gate electrode.

4. The semiconductor device according to claim 1,
wherein the eighth portion of the field plate electrode is spaced apart from the sixth portion of the first insulating film.

5. The semiconductor device according to claim 3,
wherein in plan view, the gate electrode extends in a first direction from the upper surface of the semiconductor substrate toward the upper surface of the element isolation portion, and
wherein the side surface of the second portion of the gate electrode is recessed from the side surface of the first portion of the gate electrode in a second direction orthogonal to the first direction in plan view.

6. The semiconductor device according to claim 1,
wherein the eighth portion of the field plate electrode is in contact with the sixth portion of the first insulating film, and
wherein a position of an uppermost portion of the seventh portion of the field plate electrode is lower than a position of an uppermost portion of the first insulating film positioned over the upper surface of the first portion of the gate electrode.

7. The semiconductor device according to claim 1, further comprising:
a second insulating film covering at least a part of the upper surface of the first portion of the gate electrode, the sidewall spacer positioned on the side surface of the first portion of the gate electrode, and a part of the upper surface of the semiconductor substrate; and
a silicide film formed on the upper surface of the gate electrode exposed from the second insulating film,
wherein the first insulating film covers at least the upper surface of the first portion via the second insulating film or the silicide film.

8. The semiconductor device according to claim 7,
wherein the second insulating film is disposed so as not to be formed on the upper surface of the second portion of the gate electrode.

9. The semiconductor device according to claim 1, further comprising:
a first interlayer insulating film covering the field plate electrode and formed on the first insulating film; and
a second interlayer insulating film formed on the first interlayer insulating film,
wherein an upper surface of the second interlayer insulating film is flat, and
wherein the first interlayer insulating film positioned over the upper surface of the first portion of the gate electrode and over the upper surface of the second portion of the gate electrode is covered with the second interlayer insulating film.

10. The semiconductor device according to claim 1, further comprising:
a drift region of a first conductivity type, the drift region having a predetermined depth from the upper surface of the semiconductor substrate and formed in the semiconductor substrate;
a well region of a second conductivity type opposite the first conductivity type, the well region having a predetermined depth from the upper surface of the semiconductor substrate, and the well region being formed in the semiconductor substrate;
a body region of the second conductivity type formed in the drift region;
a source region of the first conductivity type formed in the body region; and
a drain region of the first conductivity type formed in the drift region,
wherein, in plan view, the first portion of the gate electrode and the seventh portion of the field plate electrode are positioned between the drain region and the source region, and
wherein, in plan view, the well region is formed between the drift region and the element isolation portion.

11. A method of manufacturing a semiconductor device, the method comprising:
(a) preparing a semiconductor substrate having an upper surface;
(b) forming an element isolation portion in the semiconductor substrate, the element isolation portion having a predetermined depth from the upper surface of the semiconductor substrate;
(c) forming a gate insulating film on the upper surface of the semiconductor substrate;
(d) forming a gate electrode on the gate insulating film and on an upper surface of the element isolation portion;
(e) forming a sidewall spacer on a side surface of the gate electrode;
(f) forming a first insulating film over the upper surface of the semiconductor substrate and over the upper surface of the element isolation portion so as to cover an upper surface of the gate electrode and the sidewall spacer; and
(g) forming a field plate electrode on the first insulating film,
wherein the gate electrode includes:
a first portion positioned over the upper surface of the semiconductor substrate; and
a second portion positioned over the upper surface of the element isolation portion,
wherein the first insulating film includes:
a third portion positioned over the upper surface of the semiconductor substrate;
a fourth portion positioned above the third portion and positioned on the side surface of the first portion of the gate electrode via the sidewall spacer;
a fifth portion positioned over the upper surface of the element isolation portion; and
a sixth portion positioned above the fifth portion and positioned over the side surface of the second portion of the gate electrode via the sidewall spacer,
wherein the field plate electrode includes:
a seventh portion positioned over the upper surface of the semiconductor substrate; and
an eighth portion positioned over the upper surface of the element isolation portion,
wherein a position of the upper surface of the second portion of the gate electrode is higher than a position of the upper surface of the first portion of the gate electrode,
wherein the seventh portion of the field plate electrode is in contact with the fourth portion of the first insulating film, and
wherein a position of an uppermost portion of the eighth portion of the field plate electrode is lower than a position of an uppermost portion of the first insulating film positioned over the upper surface of the second portion of the gate electrode.

12. The method according to claim 11,
wherein a position of the upper surface of the element isolation portion is higher than a position of the upper surface of the semiconductor substrate.

13. The method according to claim 11,
wherein the seventh portion of the field plate electrode covers a part of the first insulating film positioned over the upper surface of the first portion of the gate electrode.

14. The method according to claim 11,
wherein the eighth portion of the field plate electrode is spaced apart from the sixth portion of the first insulating film.

15. The method according to claim 14,
wherein, in plan view, the gate electrode extends in a first direction from the upper surface of the semiconductor substrate toward the upper surface of the element isolation portion, and
wherein the side surface of the second portion of the gate electrode is recessed from the side surface of the first portion of the gate electrode in a second direction orthogonal to the first direction in plan view.

16. The method according to claim 11,
wherein the eighth portion of the field plate electrode is in contact with the sixth portion of the first insulating film, and
wherein a position of an uppermost portion of the seventh portion of the field plate electrode is lower than a position of an uppermost portion of the first insulating film positioned over the upper surface of the first portion.

17. The method according to claim 11, further comprising:
(h) between the (d) and the (f), forming a second insulating film over the upper surface of the semiconductor substrate and over the upper surface of the element isolation portion so as to cover the upper surface of the gate electrode and the sidewall spacer;
(i) between the (h) and the (f), patterning the second insulating film so as to cover at least a part of the upper surface of the first portion, the sidewall spacer positioned on the side surface of the first portion, and a part of the upper surface of the semiconductor substrate; and
(j) between the (i) and the (f), forming a silicide film on the upper surface of the gate electrode exposed from the second insulating film and on the upper surface of the semiconductor substrate,
wherein in the (f), the first insulating film covers at least the upper surface of the first portion of the gate electrode via the second insulating film or the silicide film.

18. The method according to claim 17,
wherein in the (i), the second insulating film covering the upper surface of the second portion is removed.

19. The method according to claim 11, further comprising:
(k) forming a first interlayer insulating film on the first insulating film so as to cover the field plate electrode;
(l) forming a second interlayer insulating film on the first interlayer insulating film;
(m) performing a planarization process on the second interlayer insulating film; and
(n) after the (m), performing cleaning treatment on an upper surface of the second interlayer insulating film,
wherein after the (m), the first interlayer insulating film positioned over the upper surface of the first portion of the gate electrode and over the upper surface of the second portion of the gate electrode is covered with the second interlayer insulating film,
wherein, in the (n), at least one of an aqueous solution containing hydrofluoric acid and hydrogen peroxide water and an aqueous solution containing ammonia and hydrogen peroxide water is used, and
wherein an etching rate of the first interlayer insulating film for the aqueous solution used in the (n) is higher than an etching rate of the second interlayer insulating film for the aqueous solution used in the (n).

20. The method according to claim 11, further comprising:
(o) forming a drift region of a first conductivity type in the semiconductor substrate, the drift region having a predetermined depth from the upper surface of the semiconductor substrate;
(p) forming a well region of a second conductivity type opposite the first conductivity type in the semiconductor substrate, the well region having a predetermined depth from the upper surface of the semiconductor substrate;
(q) forming a body region of the second conductivity type in the drift region; and
(r) forming a source region of the first conductivity type in the body region and forming a drain region of the first conductivity type in the drift region,
wherein, in plan view, the first portion of the gate electrode and the seventh portion of the field plate electrode are positioned between the drain region and the source region, and
wherein, in plan view, the well region is formed between the drift region and the element isolation portion.
